(19) United States
(12) Patent Application Publication
(10) Pub. No.: US 2026/0293171 A1
(43) Pub. Date: Sep. 24, 2026

(54) STRUCTURE AND METHOD TO PROVIDE CAPACITIVE JUNCTION WITH CONTACT BARS OF DIFFERENT DEPTHS

(71) Applicant: GlobalFoundries Singapore Pte. Ltd., Singapore (SG)

(72) Inventors: Yong Wah See, Singapore (SG); Guowei Zhang, Singapore (SG); Ee Jan Khor, Singapore (SG)

(21) Appl. No.: 19/083,556

(22) Filed: Mar. 19, 2025

(51) Int. Cl. H10D 1/68; H10D 1/00; H10D 80/20; H10D 84/00

(52) U.S. Cl. CPC H10D 1/714; H10D 1/042; H10D 80/215; H10D 84/217; H10D 1/694

(57) ABSTRACT

The disclosure relates to structures and methods to provide a capacitive junction with contact bars of different depths. A structure of the disclosure includes a first capacitor electrode, including a first contact bar. The first contact bar extends a first depth through an insulator layer from a lower surface of a first wire to an upper surface of an insulative component on a substrate. A second capacitor electrode includes a second contact bar parallel to the first contact bar. The second contact bar extends a second depth from a lower surface of a second wire to an upper surface of a conductive component on the substrate. The first depth and the second depth are different.

### BACKGROUND

The present disclosure relates to integrated circuit structures and, more particularly, to providing capacitive junctions in integrated circuit structures.

Capacitors are used in a wide variety of integrated circuits (ICs). As ICs have scaled smaller, forming capacitors has become more challenging. Although it is possible to form capacitors in the metal wiring layers of a device (i.e., the “back end of line” (BEOL) layers), these structures conventionally will occupy significant chip area to achieve desired amounts of capacitance. Some implementations of capacitors in metal wiring layers may require, e.g., forming additional, dedicated capacitor dielectric layers for the various capacitor devices to operate. Such techniques undesirably increase the number of masks and/or processing phases to form a device.

### SUMMARY

All aspects, examples and features mentioned below can be combined in any technically possible way.

An aspect of the disclosure provides a structure including: a first capacitor electrode including a first contact bar extending a first depth through an insulator layer from a lower surface of a first wire to an upper surface of an insulative component on a substrate; and a second capacitor electrode including a second contact bar parallel to the first contact bar, the second contact bar extending a second depth from a lower surface of a second wire to an upper surface of a conductive component on the substrate, wherein the first depth and the second depth are different.

An aspect of the disclosure includes a structure, including: an insulative component on a substrate and having an upper surface; a conductive component on the substrate and having an upper surface below the upper surface of the insulative component; a first capacitor electrode including a first contact bar extending a first depth through an insulator layer from a lower surface of a first wire in a metal wiring layer to the upper surface of the insulative component on a substrate; and a second capacitor electrode including a second contact bar parallel to the first contact bar, the second contact bar extending a second depth from a lower surface of a second wire in the metal wiring layer to the upper surface of the conductive component on the substrate, wherein the first depth and the second depth are different.

An aspect of the disclosure includes a method, including: forming a first capacitor electrode including a first contact bar extending a first depth through an insulator layer from a lower surface of a first wire to an upper surface of an insulative component on a substrate; and forming a second capacitor electrode including a second contact bar parallel to the first contact bar, the second contact bar extending a second depth from a lower surface of a second wire to an upper surface of a conductive component on the substrate, wherein the first depth and the second depth are different.

Two or more aspects described in this disclosure, including those described in this summary section, may be combined to form implementations not specifically described herein.

The details of one or more implementations are set forth in the accompanying drawings and the description below. Other features, objects and advantages will be apparent from the description and drawings, and from the claims.

### BRIEF DESCRIPTION OF THE DRAWINGS

The embodiments of this disclosure will be described in detail, with reference to the following figures, wherein like designations denote like elements, and wherein:

FIG. 1 shows a perspective view of a structure according to embodiments of the disclosure.

FIG. 2 shows a cross-sectional view of a structure according to embodiments of the disclosure.

FIG. 3 shows a partial perspective view of a structure according to embodiments of the disclosure.

FIG. 4 shows a cross-sectional view of a structure according to other embodiments of the disclosure.

FIG. 5 shows a cross-sectional view of a structure according to further embodiments of the disclosure.

FIGS. 6-11 depicts processes of forming a capacitive junction with contact bars of different heights according to embodiments of the disclosure.

It is noted that the drawings of the disclosure are not necessarily to scale. The drawings are intended to depict only typical aspects of the disclosure, and therefore should not be considered as limiting the scope of the disclosure. In the drawings, like numbering represents like elements between the drawings.

### DETAILED DESCRIPTION

In the following description, reference is made to the accompanying drawings that form a part thereof, and in which is shown by way of illustration specific illustrative embodiments in which the present teachings may be practiced. These embodiments are described in sufficient detail to enable those skilled in the art to practice the present teachings, and it is to be understood that other embodiments may be used and that changes may be made without departing from the scope of the present teachings. The following description is, therefore, merely illustrative.

It will be understood that when an element such as a layer, region, or substrate is referred to as being “on” or “over” another element, it may be directly on the other element or intervening elements may also be present. In contrast, when an element is referred to as being “directly on” or “directly over” another element, there may be no intervening elements present. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

Reference in the specification to “one embodiment” or “an embodiment” of the present disclosure, as well as other variations thereof, means that a particular feature, structure, characteristic, and so forth described in connection with the embodiment is included in at least one embodiment of the present disclosure. Thus, the phrases “in one embodiment” or “in an embodiment,” as well as any other variations appearing in various places throughout the specification are not necessarily all referring to the same embodiment. It is to be appreciated that the use of any of the following “/,” “and/or,” and “at least one of,” for example, in the cases of “A/B,” “A and/or B” and “at least one of A and B,” is intended to encompass the selection of the first listed option (a) only, or the selection of the second listed option (B) only, or the selection of both options (A and B). As a further example, in the cases of “A, B, and/or C” and “at least one of A, B, and C,” such phrasing is intended to encompass the first listed option (A) only, or the selection of the second listed option (B) only, or the selection of the third listed option (C) only, or the selection of the first and the second listed options (A and B), or the selection of the first and third listed options (A and C) only, or the selection of the second and third listed options (B and C) only, or the selection of all three options (A and B and C). This may be extended, as readily apparent by one of ordinary skill in the art, for as many items listed.

Capacitors are used in a wide variety of integrated circuits (ICs). As ICs have scaled smaller, forming capacitors has become more challenging. Although it is possible to form capacitors in the metal wiring layers of a device (i.e., the “back end of line” (BEOL) layers), these structures conventionally will occupy significant chip area to achieve desired amounts of capacitance. Some implementations of capacitors in metal wiring layers may require, e.g., forming additional, dedicated capacitor dielectric layers for the various capacitor devices to operate. Such techniques undesirably increase the number of masks and/or processing phases to form a device.

The disclosure relates to structures and methods to provide a capacitive junction with contact bars of different depths. A structure of the disclosure includes a first capacitor electrode, including a first contact bar. The first contact bar extends a first depth through an insulator layer from a lower surface of a first wire to an upper surface of an insulative component on a substrate. A second capacitor electrode includes a second contact bar parallel to the first contact bar. The second contact bar extends a second depth from a lower surface of a second wire to an upper surface of a conductive component on the substrate. The first depth and the second depth are different.

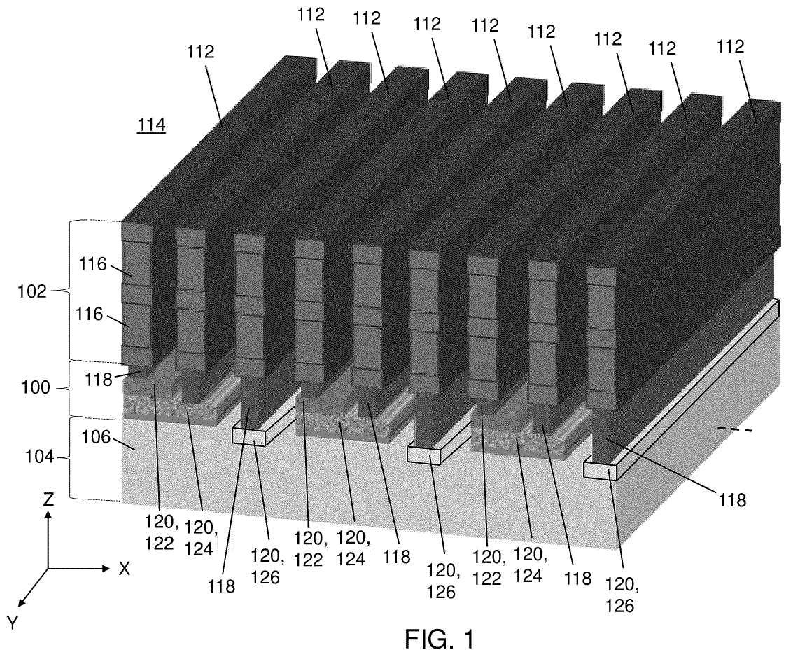

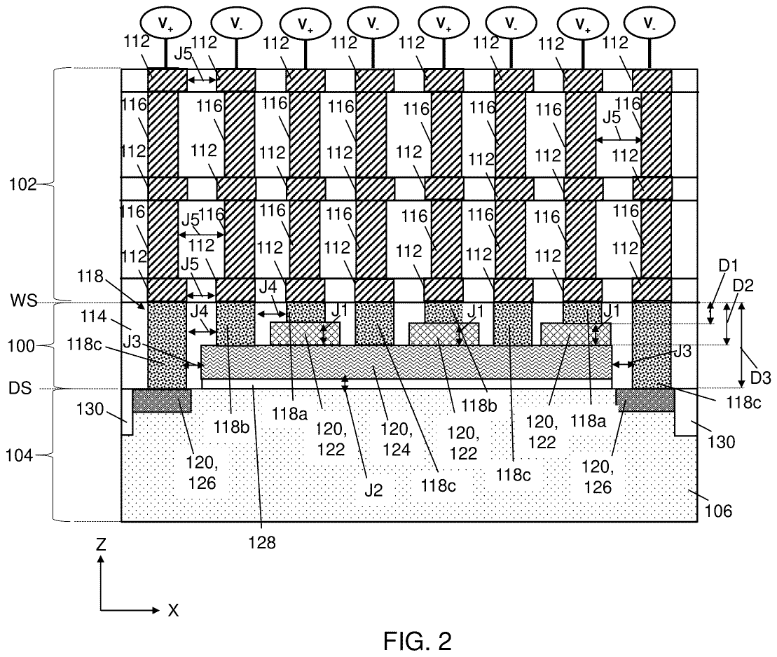

Referring to FIGS. 1 and 2, in which FIG. 1 provides a perspective view and FIG. 2 provides a cross-sectional view, an example of a structure 100 according to embodiments of the disclosure is provided. Structure 100 is physically arranged to provide a capacitive junction with contact bars having different depths relative to the bottom of overlying metal wiring layers. Structure 100 may be, e.g., vertically between a set of metal wiring layers (also known as “back end of line” (BEOL) layers) 102 of a device and over a device layer 104 having a semiconductor substrate 106 (e.g., semiconductor materials such as silicon (Si), silicon germanium (SiGe), etc.) and various components 120 thereon. Metal wiring layers 102 may include a plurality of wires 112 (shown, e.g., in three rows of wires 112 each having nine lines in the visible area) within an insulator layer 114. Insulator layer 114 may include any currently known or later developed insulative substance, including for instance oxide-based insulators (e.g., various silicon oxide compounds), nitride based insulators, and/or other insulative materials particularly those having a dielectric constant of less than approximately 3.9.

Insulator layer 114 may include one or more distinct layers of an inter-level dielectric (ILD) material, each for separating different wires 112 from each other. In this case, portions of insulator layer 114 may include etch stop layers (ESL) (not separately shown) along the upper and/or lower surface of each layer. Although insulator layer 114 is not metallic, it is considered part of metal wiring layers 102. ESL materials within insulator layer 114 may include, e.g., any material distinct from other dielectric material(s) therein and having greater resistance to etching, to structurally distinguish between vertically adjacent wiring layers. ESLs may be formed separately from other parts of insulator layer 114 and may be formed in a variety of configurations for additional electrical and physical separation between electrically active conductive materials.

Each wire 112 within insulator layer 114 may include any currently known or later developed conductive metal suitable to accumulate charge across a dielectric junction. Wires 112, in one example, may include silicon-based conductor materials or other doped semiconductor conductive materials (e.g., doped Si or silicon germanium (SiGe), metals such aluminum, (Al), copper (Cu), zinc (Zn), gold (Au), and/or other conductive materials) capable of operating as a capacitor terminal. In further embodiments, wires 112 may include one or more metals, e.g., tungsten (W), titanium (Ti), ruthenium (Ru), cobalt (Co), copper (Cu), aluminum (Al), etc. Wires 112 may be formed by depositing conductive materials on an underlying layer (e.g., another layer of dielectric material) e.g., insulator layer 114 is formed thereon. Wires 112 in different positions may be electrically decoupled from each other, e.g., they may be isolated from each other by portions of insulator layer 114. Multiple wires 112 may be present in structure 100 to provide alternating polarity terminals of distinct capacitive junctions as discussed herein.

Metal wiring layers 102 also include a set of vias 116, each connecting respective vertically aligned pairs of wires 112. Vias 116 alternatively may be in a variety of additional and/or alternative locations to those shown in FIG. 1 et seq. Each via 116 may extend vertically through insulator layer 114 completely between two vertically aligned wires 112 to provide an electrical pathway through insulator layer 114, and in some cases, wires 112 may horizontally connect two or more vias 116 located in different areas (e.g., different cross-sections) of metal wiring layers 102. Vias 116 are shown in an example to connect vertically aligned wires 112 of all rows together, but this is not required in all implementations.

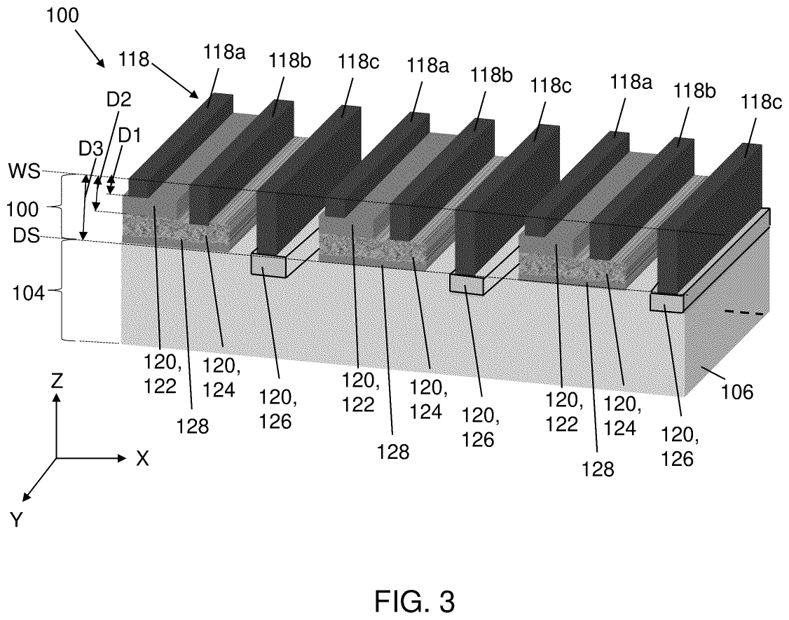

Referring now to FIGS. 2 and 3, in which FIG. 3 shows an expanded perspective view of only structure 100 and device layer 104 for clarity of illustration, various features of structure 100 between device layer 104 and metal wiring layers 102 are discussed in further detail. Structure 100 includes several contact bars 118, each extending from a lower surface WS of metal wiring layer 102 to one of several components 120 on device layer 104. Contact bars 118 may have varying depths (i.e., vertical span) below a lower surface WS of metal wiring layers 102. Contact bars 118 may be compositionally similar or identical but otherwise may be differentiated from each other based on their respective depths. Contact bars 118 of structure 100 (and other vertically oriented conductive materials discussed herein, e.g., vias 116) each may include refractory metal liners (not shown for simplicity of illustration) including, for example, ruthenium (Ru), tantalum (Ta), titanium (Ti), tungsten (W), iridium (Ir), rhodium (Rh) and platinum (Pt), etc., or mixtures of thereof. Vias 116, contact bars 118, etc., also may include other types of conductive materials, e.g., conductive nitride compounds (TaN, TiN, etc.). Contact bars 118 may differ from via 116, e.g., by extending forward of and behind the cross-section shown in FIG. 2 such that contact bars 118 are in a lengthwise parallel arrangement over device layer 104. Contact bars 118 thus may have other wires 112 and/or vias 116 coupled thereto at different locations.

First contact bar(s) 118a in structure 100 may have a first depth D1 below lower surface WS of metal wiring layers 102. First contact bar(s) 118a also may extend to an upper surface of an insulative component 122 (e.g., an insulative gate cap including one or more dielectric materials) such that first contact bar(s) 118a are in physical contact with insulative component 122. First contact bar 118a thus may constitute a first electrode. Insulative component 122 in particular may include any currently known or later developed gate cap material such that insulative component 122 may be formed on a first conductive component 124 (e.g., a gate structure having polysilicon and/or other conductive materials) by application of conventional techniques to form a transistor gate elsewhere on device layer 104. It is emphasized that first contact bar 118a alternatively may be on components 120 other than insulative component 122. First contact bar(s) 118a may be located on but not conductively coupled to insulative component(s) 122, in which case insulative component(s) 122 instead may define one or more capacitive junctions (J1) vertically between first contact bar(s) 118a and any component(s) 120 located below insulative component(s) 122.

Second contact bar(s) 118b in structure 100 may have a second depth D2 below lower surface WS of metal wiring layers 102. Second depth D2 is different (e.g., greater as shown in FIGS. 2, 3) than first depth D1. In some implementations, second depth D2 may be approximately twice as large as first depth D1 relative to the position of lower surface WS of metal wiring layers 102, but any conceivable difference in depths is also possible. Second contact bar(s) 118b thus may extend to an upper surface of a first conductive component 124, e.g., a gate conductor or similar raised conductive material such as a polycrystalline silicon (“polysilicon”) layer (or alternatively any other conductive material(s) discussed herein) over substrate 106. Second contact bar(s) 118b thus may be physically in contact with, and conductively coupled to, the conductive material(s) within first conductive component(s) 124. For instance, second contact bar(s) 118b may be on the gate conductor of a gate structure over substrate 106. In various implementations, first conductive component(s) 124 in the form of a polysilicon layer may extend lengthwise below one or more insulative component(s) 122. Insulative component(s) 122 may include various insulating materials, and thus, capacitive junctions J1 may form across insulative component(s) 122 between first contact bar(s) 118 and first conductive component(s) 124 due to the accumulation of charge on conductive material(s) at opposite ends of insulative component(s) 122.

Third contact bar(s) 118c in structure 100 may have a third depth D3 below lower surface WS of metal wiring layers 102. Third depth D3 is different from first depth D1 and second depth D2 (e.g., greater than first depth D1 and second depth D2 as shown in FIGS. 2, 3). In an example, third depth D3 may be approximately twice as large as second depth D2 or may be approximately four times as large as first depth D1. Moreover, third depth D3 may be large enough for third contact bar(s) 118c to span the entire vertical thickness of structure 100, thereby extending from lower surface WS of metal wiring layers 102 to upper surface DS of device layer 104. By comparison, first depth D1 and second depth D2 each may be less than the entire vertical span of structure 100 and thus may vertically terminate above device layer 104. Third contact bar(s) 118c may extend to an upper surface of a second conductive component 126 on substrate 106, e.g., a doped region of semiconductor material defined within (and thus positioned on) substrate 106.

Third contact bar(s) 118 thus may physically and electrically couple conductive elements in metal wiring layers 102 to substrate 106 through second conductive component 126. Structure 100 also, optionally, may include a dielectric layer 128 (e.g., one or more gate dielectric materials) vertically between substrate 106 and first conductive component(s) 124. In this case, dielectric layer 128 may have a sufficiently low vertical thickness (e.g., at most approximately one hundred nanometers nm, or other thicknesses similar to that of a gate dielectric material of a transistor) for a capacitive junction J2 may be formed form the accumulation of charge on opposite sides of dielectric layer 128. Such accumulation of charge may arise from voltages applied to substrate 106 through third contact bar(s) 118c and second conductive component(s) 126, and from voltages applied to first conductive component(s) 124 from second contact bar(s) 118. In addition, capacitive junction J3 can similarly be defined between third contact bar 118c itself and first conductive component 124 across dielectric layer 114 due to accumulation of opposite charge in these components.

Structure 100 also may include a set of horizontal capacitive junctions J4 between horizontally adjacent contact bars 118 (e.g., between first contact bar 118a and its adjacent second contact bar 118b, third contact bar 118b, or similarly between any two adjacent contact bars 118 in structure 100). Horizontal capacitive junctions J4 may be formed by coupling adjacent contact bars 118 to opposite polarity voltages, indicated schematically by “V₊” and “V₋” icons in FIG. 2 indicating electrical couplings to positive or negative voltages, respectively. Positively charged components may interdigitate with negatively charged components, thereby inducing oppositely charged capacitor electrodes at each alternating contact bar 118. The couplings to opposite polarity voltages produce opposite charge polarities in the conductive material(s) within horizontally adjacent contact bars 118. The presence of insulator layer 114 separating the oppositely charged conductors thus produces a capacitive junction and causes the adjacent contact bars 118 in structure 100 to function as capacitors.

Other capacitive junctions similarly may be defined by physically alternating components 120 having conductive properties (e.g., first conductive components 124 and second conductive component 126) with components 120 having insulative properties (e.g., insulative components 122) and/or other materials having insulative properties (e.g., dielectric layers 114, 128). In addition, metal wiring layers 102 also may include capacitive junctions J5 horizontally between adjacent wires 112 and/or vias 116, such that any capacitive junctions J1, J2, J3, J4 within structure 100 are in addition to any capacitive junctions J5 also present within metal wiring layers 102. Structure 100 may be electrically and structurally distinct from other areas of a product formed on device layer 104. Thus, trench isolations (TIs) 130 with any currently known or later developed dielectric material also may be within substrate 106 of device layer 104, e.g., to horizontally separate portions of device layer 104 with structure 100 thereover from other portions of product. Embodiments of structure 100 thus provide a larger number of capacitive junctions in a self-contained area than would be possible in metal wiring layers 102 alone and thus provide a greater total capacitance than is achievable in conventional structures.

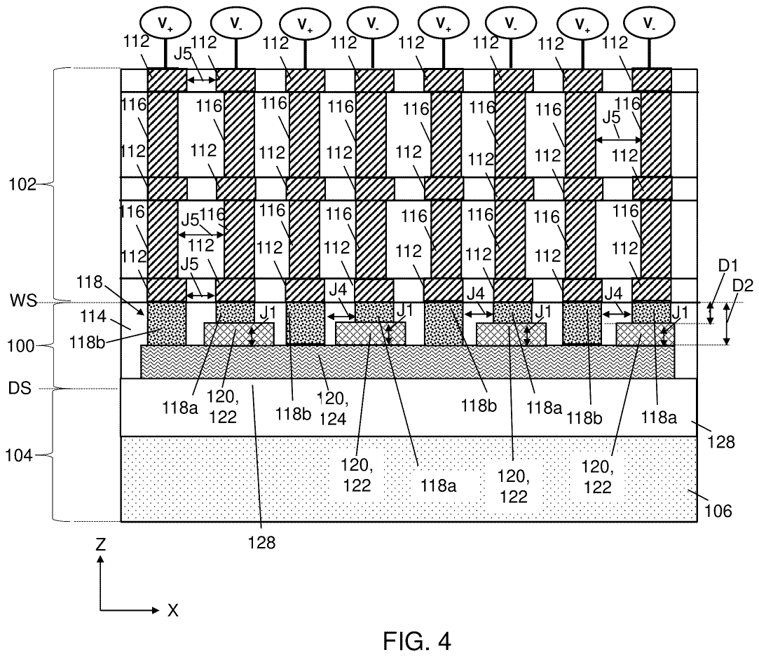

Turning to FIG. 4, structure 100 alternatively may include a different configuration of contact bars 118 and components 120. For example, structure 100 or a portion thereof may include only first contact bars 118a to insulative component(s) 122 and second contact bar(s) 118b to first conductive component(s) 124. In this case, second conductive component 126 is not present. Here, first conductive component(s) 124 may extend lengthwise over dielectric layer 128 and above substrate 106 and multiple second contact bars 118b each may be on first conductive component(s) 124 in different locations. In this example, the vertical thickness of dielectric layer 128 may be substantially (e.g., ten or more times greater) than other implementations (e.g., 1000 nm or more), such that no capacitive junctions are defined across dielectric layer 128. In addition, structure 100 may not include third contact bars 118c (FIGS. 2, 3) with third depth D3 (FIGS. 2, 3) and structure 100 also may not include second conductive component(s) 126 with contact bar(s) 118c thereto. Capacitive junction J1 (across insulative components 122) and capacitive junction J4 (between adjacent contact bars 118a, 118b) remain present in structure 100, capacitive junctions J2, J3 (FIG. 2) do not appear in such configurations. In all other respects, structure 100 and metal wiring layer 102 may be configured substantially as described in other implementations herein. Deliberately omitting second conductive component(s) 126 and third contact bars 118c, in particular, may be beneficial for low voltage applications where a larger number of series-coupled capacitors is desired.

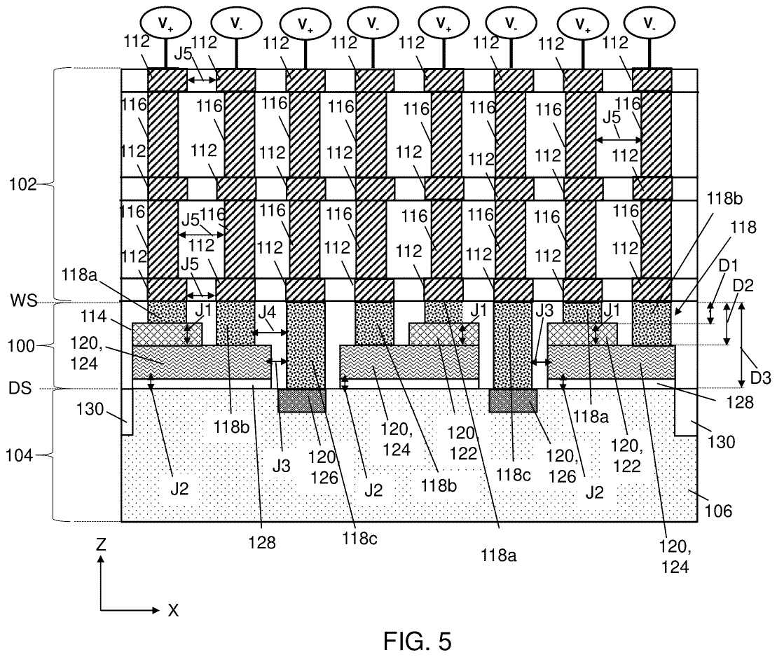

Referring now to FIG. 5, a further arrangement of structure 100 is provided. Here, structure 100 also includes three contact bars 118 (i.e., first contact bars 118a to insulative components 122, second contact bars 118b to first conductive components 124, third contact bars 118c to second conductive components 126), each having respective depths D1, D2, D3. In the illustrated example, contact bars 118a, 118b, 118c are in a different arrangement from other implementations of structure 100. Here, each first conductive component 124 (and dielectric layer 128 thereunder) may extend horizontally below only two contact bars 118 (i.e., one first contact bar 118a and one second contact bar 118b) to be located horizontally adjacent one third contact bar 118c and/or between two third contact bars 118c. In this configuration, a larger number of second conductive components 126 and/or a smaller number of first conductive components 124 may be provided to control the number and/or size of capacitive junctions J1, J2 J3, J4 at the time of manufacture, and control thus the total capacitance of structure 100 in conjunction with any capacitance within metal wiring layers 102 Increasing the number of first conductive components 124 by reducing their size, in particular, may be beneficial for high voltage applications where a larger number of parallel capacitors is desired.

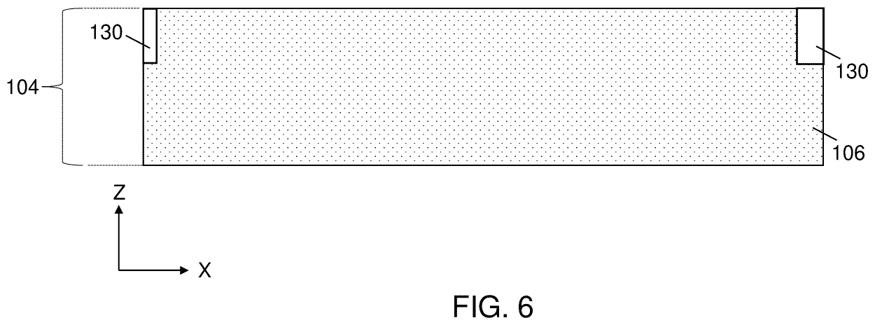

Turning now to FIG. 6, embodiments of structure 100 (FIGS. 1-5) are easily integrated into conventional processing techniques to form an IC structure by using one or more processes to form transistors, gates, etc., elsewhere on device layer 104 to form structure 100 and capacitive junctions J1, J2, J3, J4 thereof. Initially, device layer 104 may include substrate 106 and one or more TI(s) 130 for electrically separating embodiments of structure 100 (FIGS. 1-5) from other structures formed on device layer 104. Substrate 106 may include one or more semiconductor materials as discussed herein. TI(s) 130 may include one or more insulator materials (e.g., various oxide-based insulators) and may be formed by forming trenches within substrate 106 filling the trenches with dielectric material, and planarizing the dielectric material (e.g., by chemical mechanical planarization (CMP)) to yield TI(s) 130.

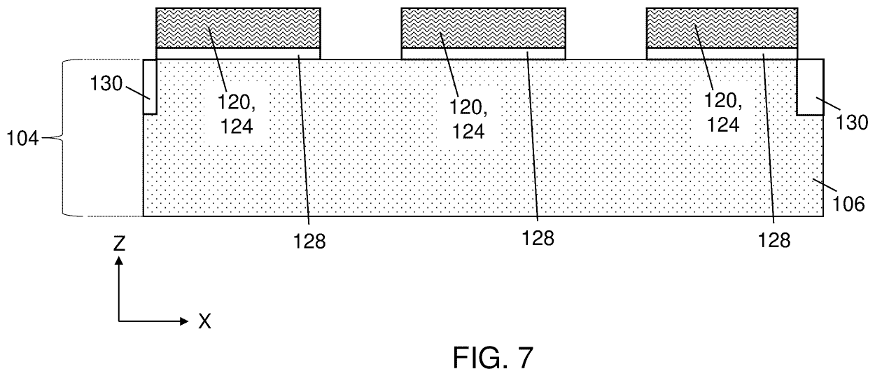

FIG. 7 depicts further processing to form dielectric layer(s) 128 and first conductive component(s) 124 thereover. Such processing may include depositing dielectric layer 128 to entirely cover device layer 104, forming first conductive component(s) 124 (e.g., polysilicon and/or other conductive or semiconductive materials) on dielectric layer 128. Optionally, the phase(s) of processing shown in FIG. 7 may include using a temporary mask (not shown) to form openings in dielectric layer 128 and first conductive component(s) 124 (e.g., by etching) to re-expose the upper surface of substrate 106 followed by removal of the mask. The temporary mask and/or other masking materials referenced herein may include a developable organic planarization layer (OPL) on the layer to be etched, a developable anti-reflective coating (ARC) layer on the developable OPL, and/or a photoresist mask layer on the developable ARC layer. In still further embodiments, dielectric layer 128 may be substantially larger in thickness to prevent capacitive junctions from forming thereacross (e.g., as in embodiments of structure(s) 100 similar to that illustrated in FIG. 4).

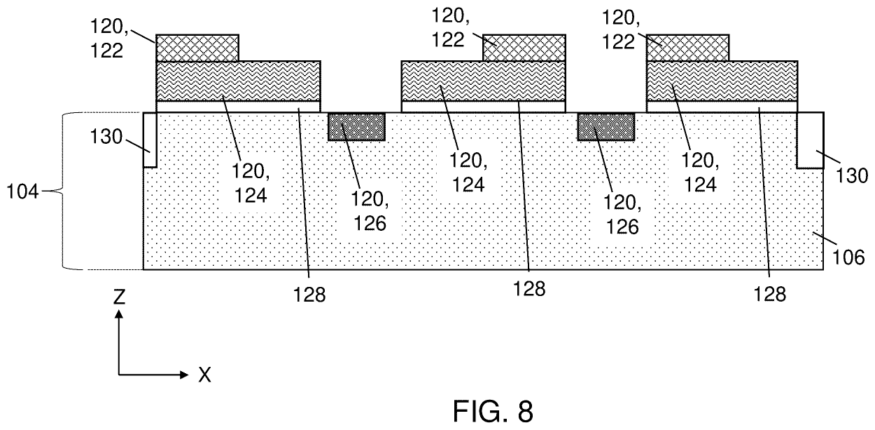

FIG. 8 depicts forming insulative components 122 on first conductive components 124, e.g., by forming a layer of dielectric material(s) over device layer 104 and first conductive components 124 and using a temporary mask (not shown) or other technique to remove targeted areas of the material, e.g., by etching followed by removal of the mask. Thus, insulative component(s) 122 only remain on a desired portion of first conductive component(s) 124 and other portions of first conductive component(s) 124 do not include insulative component(s) 122 thereon. To form second conductive component(s) 126, any exposed surfaces of substrate 106 may be doped, e.g., by ion implantation and/or any other currently known or later developed technique effective to provide doped semiconductor material(s) within substrate 106. The process(es) operable to form insulative component 122, first conductive component 124, second conductive component 126, dielectric layer 128, etc., may be simultaneous with processing of other portions of device layer 104 located elsewhere and not specifically shown.

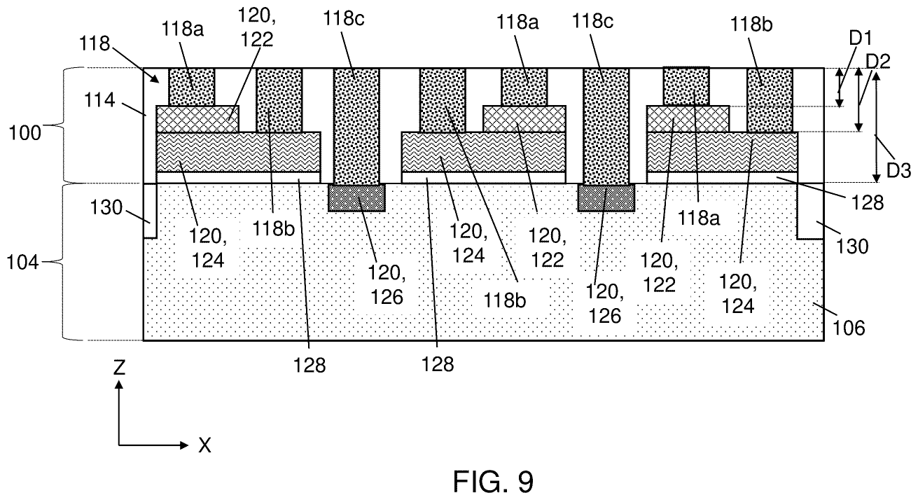

Turning to FIG. 9, continued processing to yield structure 100 may include, e.g., forming dielectric layer 114 (including ESL materials thereof where applicable) over device layer 104 and component(s) 122, 124, 126 by deposition of oxide based insulators and/or other currently known or later developed inter-level dielectric (ILD) materials to a desired height. Further processing may include forming a temporary mask (not shown) on dielectric layer 114, forming one or more temporary openings (not shown) within dielectric layer 114 by reactive ion etching (RIE) and/or vertical etchants selective to insulative materials to expose upper surfaces of component(s) 122, 124, 126. The temporary opening(s) can be filled by coating their sidewalls with refractory metal lining material, depositing or otherwise forming a conductor within the opening(s), and planarizing the conductor to yield contact bars 118. Each contact bar 118 can define first contact bar 118a, second contact bar 118b, or third contact bar 118c based on its depth within dielectric layer 114 and/or the component(s) 122, 124, 126 located thereunder. Upon the formation of contact bars 118, structure 100 is substantially complete over device layer 104.

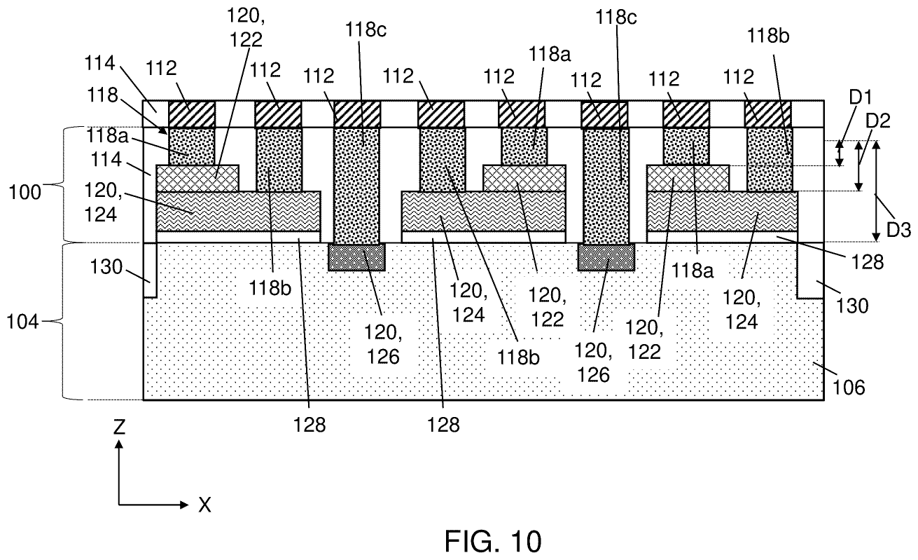

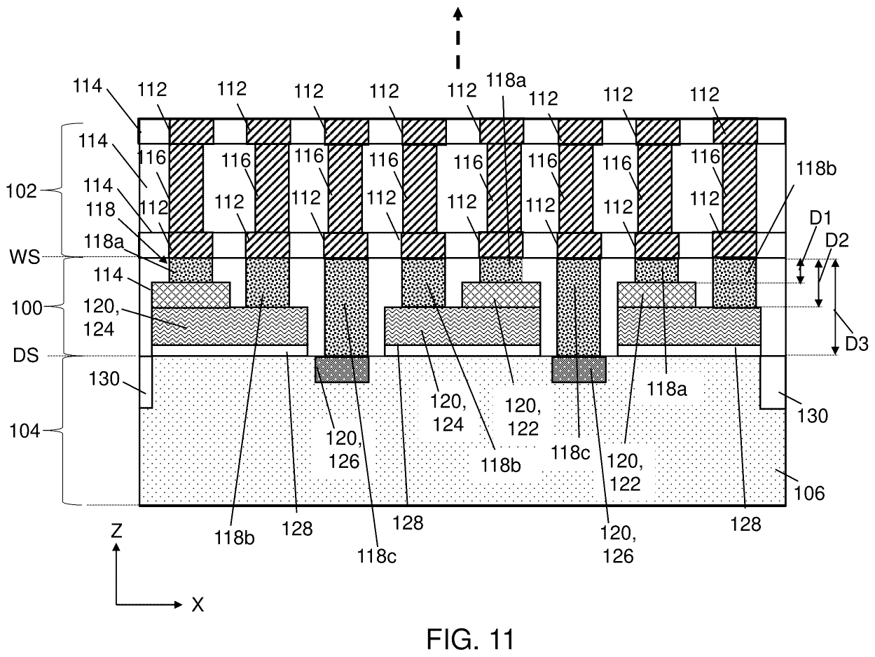

FIGS. 10 and 11 depict further processing to form metal wiring layer(s) 112 (FIGS. 1, 2, 4, 5) over structure 100. Such processing may include essentially repeating the forming of dielectric and conductive materials in the same manner shown in FIG. 9 and discussed elsewhere herein, e.g., forming another dielectric layer 114, forming openings in dielectric layer 114, and filling the openings with lining material(s) and/or additional conductor to form wires 112. Referring specifically to FIG. 11, further repetitions of these operations may yield vias 116 over wires 112 and additional wires 112 over vias 116.

Any desired number of metal wiring layers may be formed to thereby provide metal wiring layer 102 as indicated by the dashed arrow over metal wiring layer 102. The resulting configuration of layers (e.g., as shown in FIGS. 1, 2, 4, 5) may be coupled to alternating and opposite polarity voltage sources (as also shown in FIGS. 1, 2, 4, 5) to induce opposite polarity electric fields in contact bars 118a, 118b, 118c and/or component(s) 120 coupled thereto to create capacitive junctions J1, J2, J3, J4, J5 (FIGS. 2, 4, 5) within or near structure 100.

Embodiments of the disclosure provide various technical and commercial advantages, examples of which are discussed herein. Among other things, structure 100 may provide improvements in capacitive density as compared to conventional capacitors formed only in metal wiring layers 102. Embodiments of structure 100 may be particularly suitable for providing of multiple capacitors (i.e., capacitive junctions J1, J2, J3, and/or J4) in “middle of line” portions of a product between device layer 104 and metal wiring layers 102 thereover. The position and number of contact bars 118 (and in turn, the number of capacitive junctions J1, J2, J3, J4) can also be freely modified at the time of manufacture to increase or decrease the total capacitance, e.g., to suit varying voltage levels. Embodiments of structure 100, forming capacitive junctions J1, J2, J3, J4 above device layer 104 but below metal wiring layers 102, In turn, reduces surface area required to provide a desired number of capacitors within a device structure. In addition to these and other technical benefits, embodiments of the disclosure are capable of providing robust alternating polarity metal-oxide-metal (APMOM) capacitor arrangements with additional capacitive junctions therein simply by forming metal wiring layers 102 over structure 100 in any desired arrangement.

The structure and method as described herein are used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The terminology used herein is for the purpose of describing particular embodiments only and is not intended to be limiting of the disclosure. As used herein, the singular forms “a,” “an,” and “the,” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about,” “approximately,” and “substantially,” are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate +/−10% of the stated value(s).

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

What is claimed is:

1. A structure comprising:
a first capacitor electrode including a first contact bar extending a first depth through an insulator layer from a lower surface of a first wire to an upper surface of an insulative component on a substrate; and
a second capacitor electrode including a second contact bar parallel to the first contact bar, the second contact bar extending a second depth from a lower surface of a second wire to an upper surface of a conductive component on the substrate, wherein the first depth and the second depth are different.

2. The structure of claim 1, wherein the first contact bar and the second contact bar are within an insulator layer, and the insulator layer is vertically between:
a metal wiring layer including the first wire and the second wire, and
a device layer including the insulative component and the conductive component thereon.

3. The structure of claim 2, wherein the first depth is less than an entire vertical span of the insulator layer, and wherein the second depth is the vertical span of the insulator layer.

4. The structure of claim 2, wherein the first depth and the second depth are each less than an entire span of the insulator layer.

5. The structure of claim 1, wherein the first depth is less than the second depth, and wherein the first contact bar is horizontally between two second contact bars.

6. The structure of claim 1, wherein a portion of the conductive component is below the insulative component, and a vertical capacitive junction is between the first contact bar and the conductive component.

7. The structure of claim 1, wherein a horizontal separation between the second contact bar and the conductive component causes a horizontal capacitive junction to be between the second contact bar and the conductive component.

8. A structure comprising:
an insulative component on a substrate and having an upper surface;
a conductive component on the substrate and having an upper surface below the upper surface of the insulative component;
a first capacitor electrode including a first contact bar extending a first depth through an insulator layer from a lower surface of a first wire in a metal wiring layer to the upper surface of the insulative component on a substrate; and
a second capacitor electrode including a second contact bar parallel to the first contact bar, the second contact bar extending a second depth from a lower surface of a second wire in the metal wiring layer to the upper surface of the conductive component on the substrate, wherein the first depth and the second depth are different.

9. The structure of claim 8, wherein the conductive component is a gate conductor of a gate structure over the substrate.

10. The structure of claim 9, wherein the insulative component is a gate cap of the gate structure over the substrate.

11. The structure of claim 10, wherein a vertical capacitive junction is between the gate structure and the first contact bar across the gate cap.

12. The structure of claim 8, wherein the conductive component is a doped semiconductor region on the substrate.

13. The structure of claim 12, wherein the insulative component is a gate dielectric layer below a gate conductor, and the first contact bar includes the gate conductor.

14. The structure of claim 13, wherein a vertical capacitive junction is between the gate conductor and the substrate across gate dielectric layer.

15. A method comprising:
forming a first capacitor electrode including a first contact bar extending a first depth through an insulator layer from a lower surface of a first wire to an upper surface of an insulative component on a substrate; and
forming a second capacitor electrode including a second contact bar parallel to the first contact bar, the second contact bar extending a second depth from a lower surface of a second wire to an upper surface of a conductive component on the substrate, wherein the first depth and the second depth are different.

16. The method of claim 15, further comprising forming the first contact bar and the second contact bar are within an insulator layer, and the insulator layer is vertically between:
a metal wiring layer including the first wire and the second wire, and
a device layer including the insulative component and the conductive component thereon.

17. The method of claim 16, wherein the first depth is less than an entire vertical span of the insulator layer, and wherein the second depth is the vertical span of the insulator layer.

18. The method of claim 16, wherein the first depth and the second depth are each less than an entire span of the insulator layer.

19. The method of claim 15, further comprising forming a portion of the conductive component below the insulative component, and a vertical capacitive junction is between the first contact bar and the conductive component.

20. The method of claim 15, wherein a horizontal separation between the second contact bar and the conductive component causes a horizontal capacitive junction to be between the second contact bar and the conductive component.
